(19) United States
(12) Patent Application Publication
(10) Pub. No.: US 2005/0191985 A1
(43) Pub. Date: Sep. 1, 2005

(54) Diode ring configuration for harmonic diode mixers

(76) Inventors: Thomas A. Bos, Santa Clara, CA (US); Edmar Camargo, San Jose, CA (US)

Correspondence Address: CHRISTIE, PARKER & HALE, LLP, P.O. BOX 7068, PASADENA, CA, 91109-7068, US

(21) Appl. No.: 10/789,237

(22) Filed: Feb. 27, 2004

(51) Int. Cl. H04B 1/04; H01Q 11/12; H03K 9/00; H04L 27/06

(52) U.S. Cl. 455/326; 455/318; 455/118

(57) ABSTRACT

A sub-harmonic mixer having at least one diode ring array used for up-conversion in a transmitter and for down-conversion in a receiver. Each diode ring array has a plurality of (e.g., four) diode rings arranged in parallel. The diode ring array may be connected in parallel or series with the signal flowing in the circuit. In a transmitter, a local oscillator (LO) generates an LO frequency signal. The sub-harmonic mixer generates a signal having twice the LO frequency using the LO frequency signal, and multiplies it to an intermediate frequency (IF) signal to generate a radio frequency (RF) signal for transmission. The sub-harmonic mixer may be a sub-harmonic image rejection mixer having two diode ring arrays (i.e., sub-harmonic mixers) that are coupled together through a 90° hybrid at an input and a 90° hybrid at an output. In a receiver, the sub-harmonic mixer receives an input RF signal and generates an output IF signal in a reverse process.

### FIELD OF THE INVENTION

The present invention is related to radio transmitters, and more particularly to a diode ring structure for harmonic mixers.

### BACKGROUND

In conventional radio systems, linear modulation is employed at the transmitter side to translate the signal frequency spectrum of an intermediate frequency (IF) signal to a higher frequency spectrum around a carrier frequency. The carrier frequency is higher than the frequency of the IF signal, and is better suited to propagate through a communication medium. This process, also known as heterodyning, can be accomplished by multiplying the signal, [1+x(t)]cos(ω₁t), by a sinusoid, e.g., cos(ω₂t), generated by a local oscillator (LO) as illustrated, for example, by the following equation: 2[1+x(t)]cos(ω₁t)cos(ω₂t)=x(t)cos(ω₁+ω₂)t+x(t)cos(ω₁−ω₂) t+2cos(ω₂t)+

The multiplication, which is typically performed by a mixer, generates the sum and difference of frequencies of the signals. Hence, the multiplication translates the frequency of the signal to two new frequencies. The block diagram of FIG. 1, for example, qualitatively illustrates the translation of the spectrum contained around ω₁ to a higher frequency around ω₂. The spectrum of each signal is depicted in FIG. 2, where the higher sideband, namely, ω₁+ω₂, is the desired signal. In other applications, the lower sideband, namely, ω₁−ω₂, may be the desired signal. The LO frequency and lower (or upper) sideband signals observed at the antenna port usually are unwanted signals. The process described is said to “up-convert” the information from a low frequency to a high frequency to be transmitted through radio waves. The inverse process, i.e. “down-conversion”, does the opposite. In other words, down-conversion translates the information contained in a high frequency carrier to a low frequency.

The output spectrum can be obtained with the use of a filter after the mixer or with an image rejection mixer through a process known as Single Side Band (SSB) generation. An image rejection mixer is typically composed of two common mixers connected through a hybrid that provide a proper phasing for image rejection. The SSB generation ideally should suppress all unwanted signals and transmit only the desired information. In real circuits, however, there is always a certain amount of leakage, requiring the use of a filter to maintain the level of unwanted signals within standards. It should be noted, however, that the better the suppression of the image rejection mixer, the easier it is to design the filter and the lower its cost.

Therefore, it is desirable to provide an image rejection mixer having the best suppression characteristics for the unwanted signals that can be obtained with a certain technology.

### SUMMARY

In an exemplary embodiment according to the present invention, a sub-harmonic mixer is provided. The sub-harmonic mixer includes an input for receiving a first signal having a first frequency and a second signal having a second frequency, an output for outputting a third signal having a third frequency, and at least one diode ring array, each having a plurality of diode rings arranged in parallel. At least one diode ring array receives the first signal and the second signal, generates a fourth signal having twice the second frequency, and multiplies the fourth signal to the first signal to generate the third signal.

When operating as an up-converter, for example, the first frequency may be an IF frequency, the second frequency may be an LO frequency, and the third frequency may be an RF frequency. When operating as a down-converter, for example, the first frequency may be an RF frequency, the second frequency may be an LO frequency, and the third frequency may be an IF frequency.

In another exemplary embodiment of the present invention, a transmitter including a sub-harmonic mixer and an oscillator is provided. The sub-harmonic mixer has at least one diode ring array, each having a plurality of diode rings arranged in parallel. The sub-harmonic mixer receives an intermediate frequency (IF) signal and translates the IF signal to a transmission signal having a transmission frequency. The oscillator generates a local oscillator (LO) frequency signal having an LO frequency. The sub-harmonic mixer receives the LO frequency signal, generates a signal having twice the LO frequency, and multiplies the signal having twice the LO frequency to the IF signal using said at least one diode ring array to generate the transmission signal.

In yet another exemplary embodiment of the present invention, a method of generating a transmission signal having a transmission frequency from an intermediate frequency (IF) signal is provided. A local oscillator (LO) frequency signal having an LO frequency is generated. A signal having twice the LO frequency is generated using a sub-harmonic mixer including at least one diode ring array, each having a plurality of diode rings arranged in parallel The signal having twice the LO frequency is multiplied to the IF signal using a sub-harmonic mixer to generate the transmission signal.

In still another exemplary embodiment of the present invention, a receiver includes a sub-harmonic mixer having at least one diode ring array, each having a plurality of diode rings arranged in parallel. The sub-harmonic mixer receives a transmission signal having a transmission frequency and translates the transmission signal to an intermediate frequency (IF) signal. An oscillator generates a local oscillator (LO) frequency signal having an LO frequency. The sub-harmonic mixer receives the LO frequency signal, generates a signal having twice the LO frequency, and applies the signal having twice the LO frequency to the transmission signal using said at least one diode ring array to generate the IF signal.

### BRIEF DESCRIPTION OF THE DRAWINGS

These and other aspects of the invention may be understood by reference to the following detailed description, taken in conjunction with the accompanying drawings, wherein:

FIG. 1 is a simplified block diagram of a transmitter, which illustrates mixing between an intermediate frequency (IF) signal and a local oscillator (LO) frequency signal;

FIG. 2 illustrates a spectrum of signal including an IF signal having frequency ω₁, a leakage LO frequency signal having frequency ω₂, and lower and upper side band signals having frequencies ω₂−ω₁ and ω₂+ω₁, respectively;

FIG. 3A is a transmitter having a sub-harmonic mixer in an exemplary embodiment of the present invention;

FIG. 3B illustrates a spectrum of signal including an IF signal having frequency ω₁, a leakage LO frequency signal having frequency ω₂/2, a leakage 2×LO frequency signal having frequency ω₂ and lower and upper side band signals having frequencies ω₂−ω₁ and ω₂+ω₁, respectively;

FIG. 4A is a block diagram illustrating a diode ring array in the transmitter of FIG. 3A, wherein the diode rings of the array are connected in parallel between a common connection point and ground;

FIG. 4B is a block diagram illustrating a diode ring array for a sub-harmonic mixer in another exemplary embodiment of the present invention, wherein the diode rings are parallel to one another, and are in series with and form a signal path between input and output of the diode ring array;

FIG. 5A is a top view photograph of an implementation of the diode ring array of FIG. 4A;

FIG. 5B is a top view photograph of an implementation of the diode ring array of FIG. 4B;

FIG. 6 is an equivalent electrical circuit of a diode;

FIG. 7 is a graph illustrating a comparison between a second harmonic LO power leakage generated by an image rejection mixer having the diode ring array of FIGS. 4 and 5, and a second harmonic LO power leakage generated by an image rejection mixer having a single diode ring;

FIG. 8 is a graph illustrating a comparison between an input 1 dB compression power level of an image rejection mixer having the diode ring array of FIGS. 4 and 5, and an input 1 dB compression power level of an image rejection mixer having a single diode ring;

FIG. 9 is a transmitter having a sub-harmonic mixer in another exemplary embodiment of the present invention;

FIG. 10 is a block diagram illustrating a diode ring array in the transmitter of FIG. 9;

FIG. 11 is a graph illustrating a conversion loss of an image rejection mixer of FIG. 9 operating as a down-converter;

FIG. 12 is a graph illustrating a conversion loss of the image rejection mixer of FIG. 9 operating as an up-converter;

FIG. 13A is a graph illustrating an output power level of LO frequency amplifier and 2×LO power level at RF port of the image rejection mixer of FIG. 9;

FIG. 13B is a graph illustrating an output power level of a mixer having a series-connected diode ring array;

FIG. 14 is a graph illustrating an input P_{1dB} power level for the image rejection mixer of FIG. 9, operating as up- and down-converter;

FIG. 15 is a receiver in another exemplary embodiment of the present invention; and

FIG. 16 is a graph illustrating the performance of a mixer having the diode ring array of FIG. 4B.

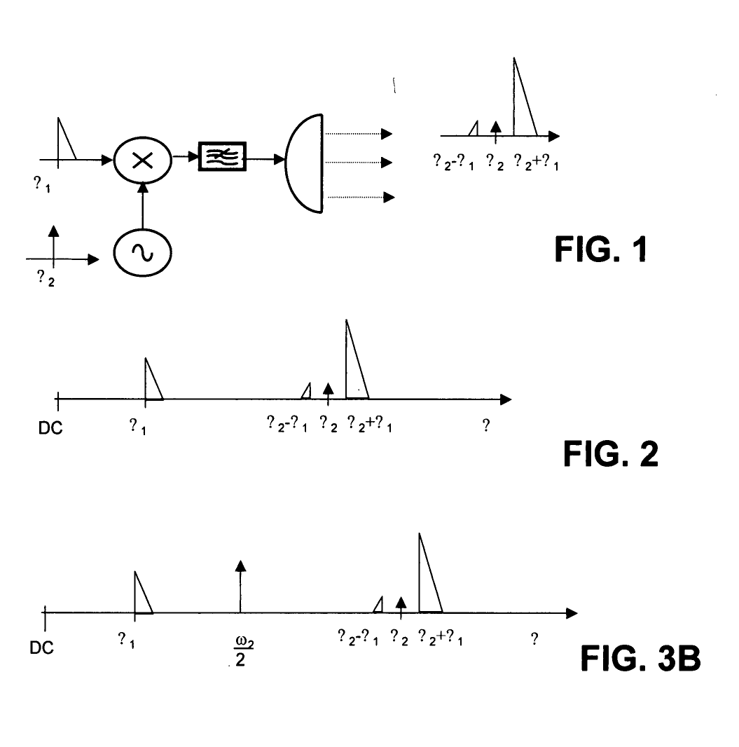

### DETAILED DESCRIPTION

In exemplary embodiments of the present invention, an image rejection mixer including sub-harmonic mixers (i.e., a sub-harmonic image rejection mixer) greatly reduces the level of LO leakage, compared to a fundamental image rejection mixer. One or more sub-harmonic mixers, each may simply be referred to as a “mixer” or a “harmonic mixer” hereinafter, are implemented on Monolithic Microwave Integrated Circuit (MMIC), and are based on the switching function of a ring of “anti-parallel” diodes. The sub-harmonic image rejection mixer may also be referred to as a “mixer” or a “sub-harmonic mixer” herein. The term anti-parallel as used herein refers to the fact that the two diodes in the diode ring are in a parallel relationship, but are oriented in opposite directions of each other.

The sub-harmonic mixer includes a number of parallel diode rings (i.e., a diode ring array), each including two diodes that are electrically connected in anti-parallel. The sub-harmonic image rejection mixer includes two such diode ring arrays. The diode rings are pumped at a local oscillation (LO) frequency. The sub-harmonic mixer generates a signal having 2×LO frequency, and multiplies it to an intermediate frequency (IF) signal to generate the RF (i.e., transmission) signal “centered around” (i.e., “having”) the RF frequency. The RF frequency is a sum of or a difference between the 2×LO frequency and the intermediate frequency. The RF frequency may be approximately equal to 2×LO frequency when the LO frequency is significantly higher than the IF.

This topology generates a substantially symmetrical waveform with very low content of even harmonics, in particular of 2×LO frequency. The sub-harmonic mixer in the exemplary embodiments of the present invention demonstrates both high isolation and good linearity.

The RF signal (i.e., transmission signal) having the RF frequency is the output signal that is obtained by applying the LO frequency signal to the sub-harmonic mixer. Since the diode is a non-linear element, it generates internally the frequency component 2×LO, which is multiplied with the IF signal and is the one generating the transmission signal. The fundamental LO signal is substantially rejected in the sub-harmonic mixer of the present invention.

The sub-harmonic mixer or the sub-harmonic image rejection mixer, for example, may be applied in Ka-band and/or higher frequency bands, for example, in 36-44 Giga Hertz (GHz) range. Since the LO frequency is approximately one half of the RF frequency, a high output power level of the LO amplifier (i.e., LO driver amplifier) is only required at lower frequencies, which may lead to the reduced cost for the transmitter and receiver.

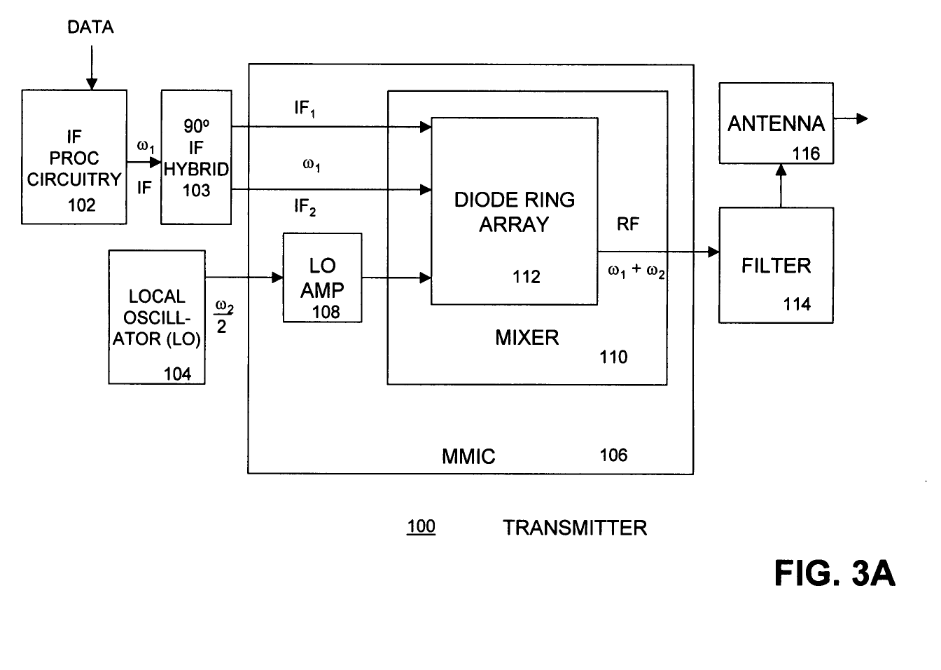

FIG. 3A is a block diagram of a transmitter 100 according to an exemplary embodiment of the present invention. The transmitter 100 includes IF processing circuitry 102 for receiving data, and generating (e.g., via modulating the data) an IF signal having frequency ω₁. An IF hybrid 103 receives the IF signal and generates two quadrature IF signals, IF₁ and IF₂, that are offset in phase by 90° of each other and each having frequency ω₁. The transmitter 100 also includes a local oscillator 104, which generates an LO frequency signal having frequency ω₂/2, which is approximately one half the frequency of the RF signal used for transmission.

The LO frequency signal is amplified by an LO amplifier 108. The LO amplifier 108 is implemented on an MMIC 106 together with a sub-harmonic mixer 110. In other embodiments, the LO amplifier may be implemented on a separate chip from the sub-harmonic mixer 110. In still other embodiments, the LO amplifier may be not used. The IF signals, IF₁ and IF₂, are mixed in the sub-harmonic mixer 110 with the amplified LO frequency signal having a frequency ω₂/2. In more detail, the sub-harmonic mixer 110 generates a signal having twice the frequency of the LO frequency signal (i.e., 2×LO frequency signal), and multiplies it to the IF₁ and IF₂ signals to generate the mixed signal. The mixed signal may then be filtered by a filter 114 to remove other components from the mixed signal to generate the RF signal having frequency ω₁+ω₂, which is transmitted by an antenna 116. In other embodiments, the filter 114 may also be implemented on the MMIC 106.

The sub-harmonic mixer 110 includes a diode ring array 112, which receives the IF₁ and IF₂ signals and the LO signal. The mixer 110 generates a transmission signal having the frequency of the RF signal. In practice, the sub-harmonic mixer 110 generates two signals, one having the frequency of LO frequency+IF and another having the frequency of 2×LO frequency+IF, but only the latter is transmitted as the RF signal, since the former is substantially rejected internally to the diode ring array 112. The sub-harmonic mixer 110 can also select the other sideband, i.e., (2×LO frequency−IF), for transmission by proper selection of ports on the IF 90° hybrid.

The sub-harmonic mixer 110 (and the MMIC 106), for example, may be fabricated using diodes made from field emission transistor (FET) based technologies, and may be capable of reducing the level of 2×LO leakage far below the level obtained by conventional structures while providing high linearity. By way of example, the MMIC 106 may be fabricated using 0.25 μm gate length Pseudomorphic High Electron Mobility Transistor (PHEMT) technology available from Fujitsu.

It can be seen in FIG. 3B, that the spectrum of signals for the sub-harmonic mixer of FIG. 3A has ω₂/2 component in addition to the frequency components of the spectrum for the fundamental mixer shown in FIG. 2.

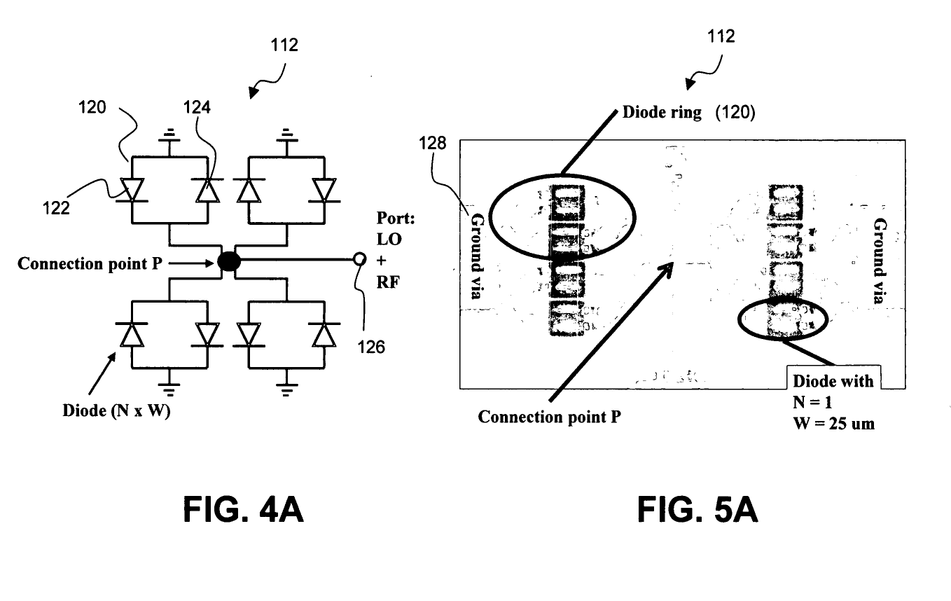

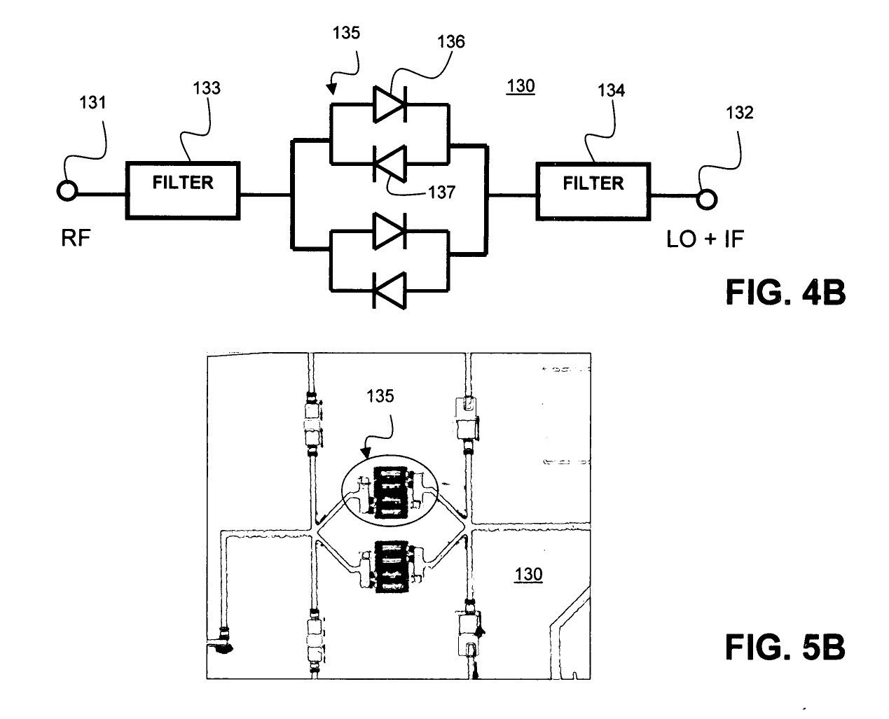

FIG. 4A is a block diagram that illustrates a topology of the diode ring array 112 of FIG. 3A. FIG. 5A is a top view photograph of the actual implementation of the diode ring array 112. For one finger diode with a small anode width W, the parasitic elements (e.g., junction capacitance and reverse leakage current) are very low, resulting in low second harmonic leakage power generation within the ring. Therefore, the width of the diode should be selected to be the minimum possible for a given technology. However, RF power performance of unity rings is low. Such low RF power performance can be overcome, for example, by coupling several diode rings (R=2, 3, 4, 5, 6, 7, 8, etc.) in parallel at a common connection point P, to achieve, for example, desired RF power and hence linearity.

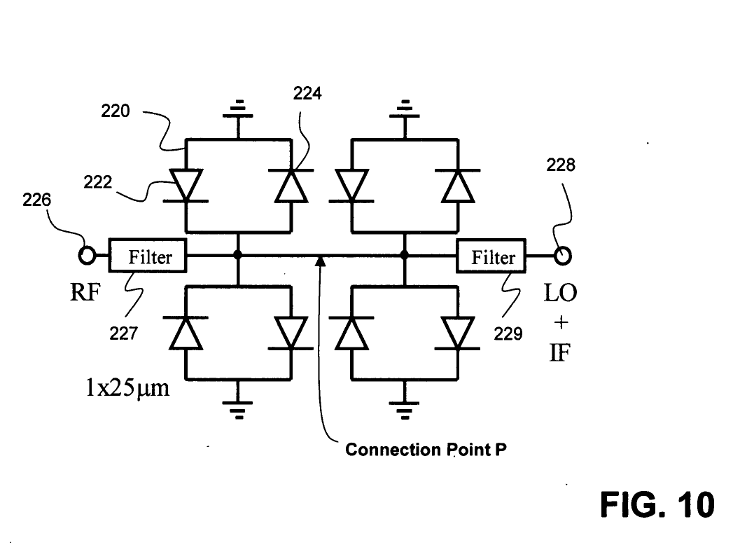

It can be seen in FIG. 4A that the diode ring array 112 includes four diode rings 120, each having two diodes 122 and 124 that are electrically connected together in anti-parallel relationship with each other, between ground and the connection point P. Hence, four diode rings 120 are connected in parallel between the connection point P and ground, and they may be referred to as “parallel-connected” diode rings. In other words, all of the diode rings 120 are in parallel with the signal flowing in the circuit. The connection point P is electrically connected to a port 126, through which the output of the sub-harmonic mixer is provided to the filter 114. In other embodiments, the diode ring array may have a different number (e.g., 2, 3, 5, 6, 7, 8, etc.) of diode rings that are connected in parallel. While it is not shown explicitly in FIG. 4A, the diode ring array 112 in practice may also have a filter at an input and a filter at an output, much like the diode ring array of FIG. 10 described below.

The diode ring array 112 of FIG. 5A has been fabricated using the PHEMT technology where the minimum anode width W is 25 μm. It can be seen in FIG. 5 that each diode has one finger (i.e., N=1) with an anode gate finger width W, which can be 25 μm, for example. Since there are four diode rings 120 in the diode ring array 112, the total effective diode width W_{eff} for all anti-parallel diode rings connected between the connection point P and ground is: W_{eff}=R×(2×N×W)=4×(2×1×25) μm=200 μm. The effective diode size W_{eff} may of course be different in other embodiments, depending on the technology used, the number of diode rings, the width of each diode, and/or the like. In the parallel-connected diode ring array 112 of FIG. 4A, all diode rings are connected on one side to the connection point P. On the other side, the diode rings are electrically connected to via holes 128, which form the connection to ground.

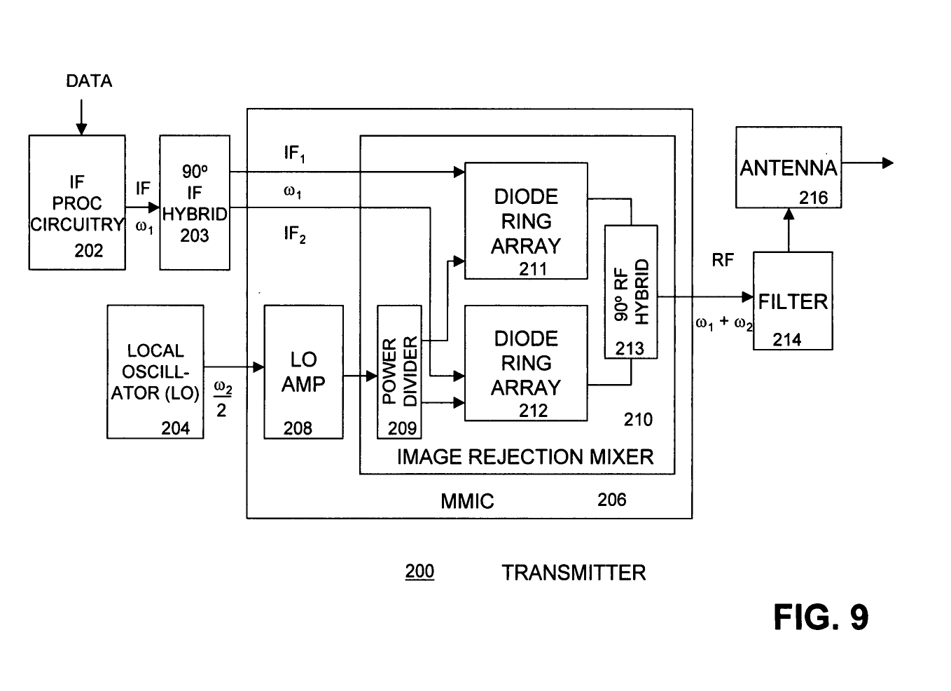

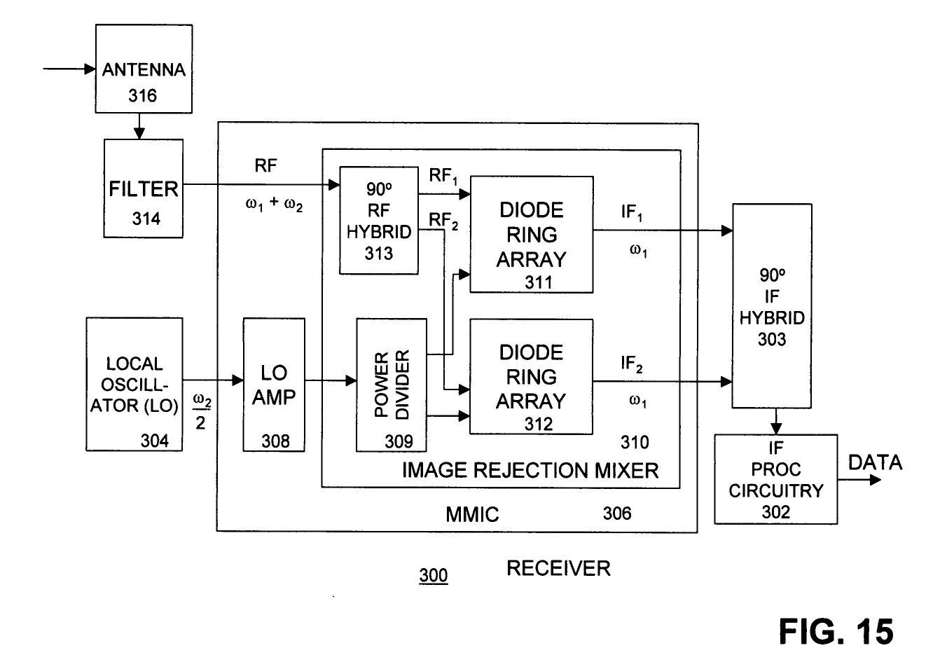

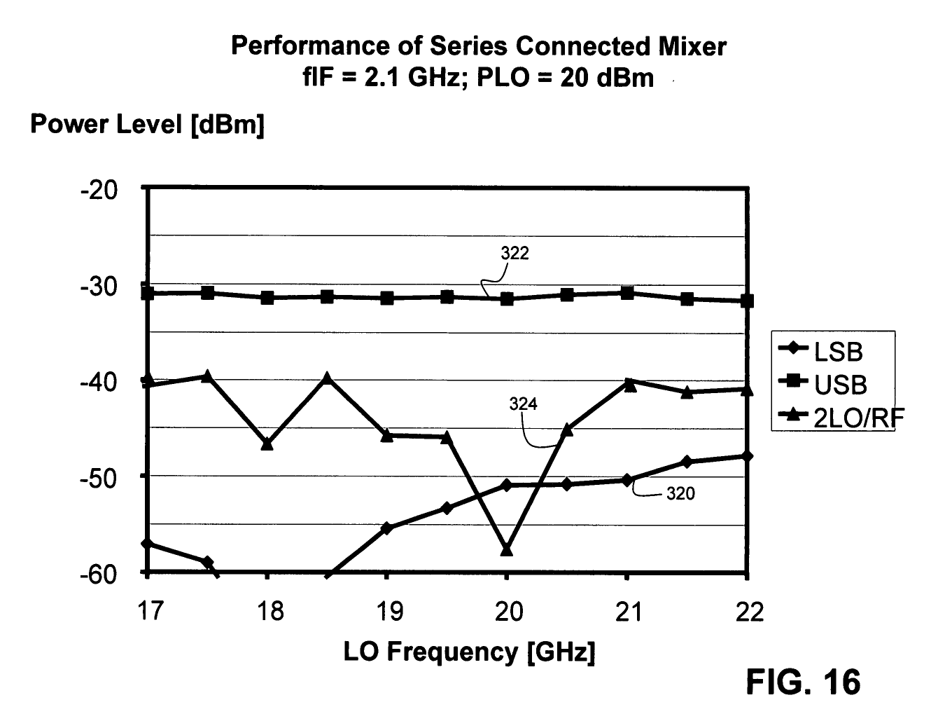

FIG. 4B is a diode ring array 130 in another exemplary embodiment of the present invention. The diode ring array 130 may replace the diode ring array 112 of FIG. 3A, the diode ring array 211 or 212 of FIG. 9 described below, and/or the diode ring array 311 or 312 of FIG. 15 described below. Of course, the operational characteristics of the image rejection mixer will change when the diode ring array 130 is used. A graph illustrating power levels of a mixer having the diode ring array 130 is shown in FIG. 16 below.

The diode ring array 130 as shown in FIG. 4B has two parallel diode rings 135 that are connected between the input and output ports 131, 132. Each diode ring 135 has diodes 136 and 137 that are connected in anti-parallel relationship with one another, and in series with signal with no ground connection. While only two diode rings 135 are shown in FIG. 16, in practice, the diode ring array may have other number (e.g., 3, 4, 5, 6, 7, 8, and the like) of diode rings connected in parallel.

An RF port 131 is on one side of the diode rings 135 and an LO+IF port 132 is on the other side. A diplexer can be used to separate the LO from IF. A filter 133 is disposed between the diode rings 135 and the port 131, and a filter 134 is disposed between the diode rings and the port 132. While the diode rings are connected in parallel with respect to one another, since they are electrically connected between ports 131 and 132, thereby forming a signal path between input and output ports, the diode ring array 130 may be referred to as “series-connected,” which means that all diode rings are in series with the signal flowing in the circuit. In other words, for the series-connected diode ring array 130, all diode rings are connected on one side to either an RF or LO line and on the other side either to the LO or RF line. FIG. 5B is a top view photograph of an implementation of the diode ring of FIG. 4B.

Ideally, all harmonics of the fundamental LO frequency should be generated within the ring. If the ring is symmetrical, all even harmonics should cancel in the ring, and only odd harmonics should be present outside of it at the RF port. The isolation of the second harmonic local oscillator frequency, which falls within the wanted RF bandwidth, at the RF port of the sub-harmonic mixer should ideally be infinite.

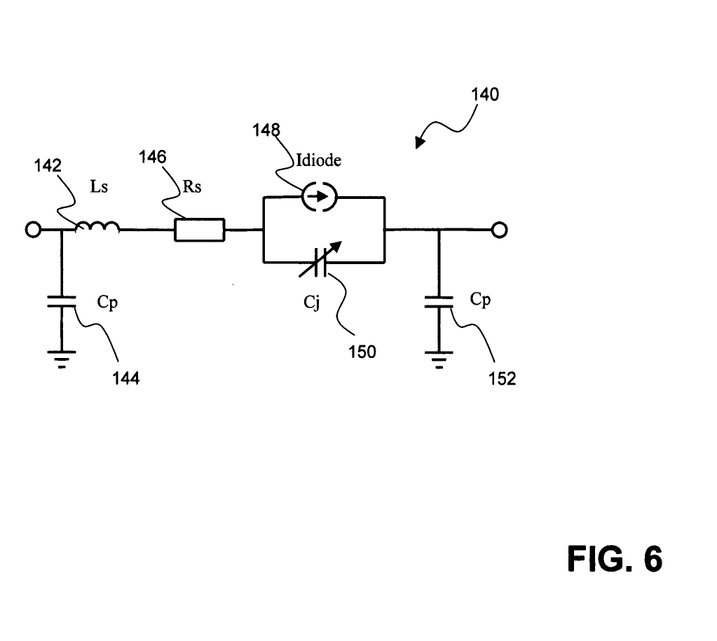

In practice, however, every diode can be viewed as a combination of the current source and the junction capacitance, as shown in FIG. 6. An equivalent electrical circuit 140 of a diode shown in FIG. 6 has a current source 148 in parallel with a junction capacitance 150. The parallel current source and junction capacitance are in series with inductance 142 and resistance 146. Input and output ends of the diode model are coupled via capacitors 144 and 152, respectively, to ground.

The current source 148 is one of the elements used to effect the switching function. To make an ideal switch, on-resistance should be a short circuit during 50% of the duty cycle and open circuit for the complementary cycle. Unfortunately, these conditions are only approximately met by real diodes. The on-resistance is different from zero, degrading conversion loss, and the reverse leakage current is different from open circuit, degrading isolation. Additionally, the junction capacitance 150 in parallel contributes to further degradation of switching performance.

In the realization of planar diodes in FET or HEMT technologies, there are many unavoidable parasitics and it is difficult to build perfectly symmetrical diodes. Those are responsible for a non-ideal switching function of the diodes. As a result, leakage power at the second harmonic of the LO is generated. The list of parasitics that influence the operation of a diode as ideal switch, is manifold: it includes the junction capacitance and the reverse leakage current; the unsymmetrical layout of diodes in FET or HEMT technologies and the difference between anode and cathode connections. They all contribute to an imbalance in the diode ring.

Further, in planar IC technology, the layout of two diodes on a ring configuration is not fully symmetrical. Therefore, the circuit impedance is different depending on whether LO is connected to anode or cathode. Simulation for a diode ring considering the equivalent circuit of FIG. 6, shows a difference of a few mS in admittance at 40 GHz. As consequence of those parasitics, even harmonic levels of the diodes will be slightly different from each other, resulting in degradation of the 2×LO to RF isolation.

A common way to increase the isolation is to reduce the diode size. The parasitic capacitance and reverse leakage currents become smaller and the differences in anode and cathode asymmetries are reduced. Now the pumped diode ring becomes comparable to the ideal switch function. However, a reduced linearity of the sub-harmonic mixer also results from the diode size reduction.

As described above, in exemplary embodiments of the present invention, instead of having one diode ring with large size diodes, several rings are connected in parallel. Due to the parallel combination of the diode rings, the effective total diode size is increased. As a consequence, the power performance is recovered and good linearity can be achieved. The amount of second harmonic LO power, that still leaks from each individual ring, adds up at the output, but it is considerably lower than the one generated by a single ring of equivalent diode size.

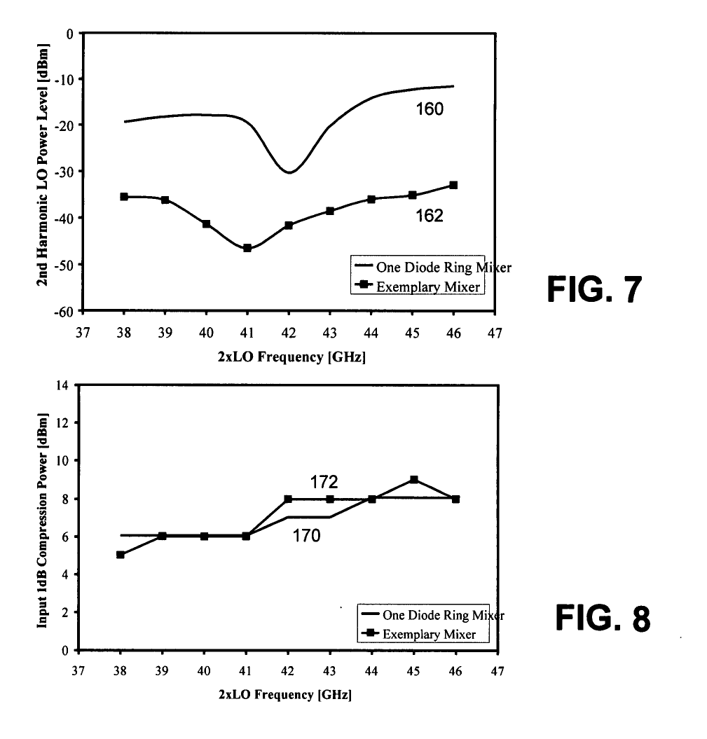

For comparison, when only one diode ring (R=1) with long width is used (i.e., N=3 fingers and width of W=33.33 μm), the total effective size is also: W_{eff}=R×(2>N×W)=1×2×3×33.33 μm≅200 μm. The large individual diode has a larger junction capacitance and a larger reverse leakage current than the single finger diode in exemplary embodiments of the present invention. Besides, the layout connections of the anode and cathode may also be different. This results in a high second harmonic leakage current. A second harmonic LO leakage level of a sub-harmonic image rejection mixer built with this diode ring is shown as a plot 160 in FIG. 7 for the 38 to 46 GHz frequency range. In addition, measured input 1 dB compression power of the image rejection mixer (having a single diode ring with large diodes) is shown as a plot 170 in FIG. 8. It can be seen that it has a typical value of 6 to 8 dBm in the 38 to 46 GHz frequency range.

A sub-harmonic image rejection mixer built with the diode ring array 112 has a total effective diode size which is similar to the mixer built with the diode ring having larger diodes, namely, 200 μm. The level of the second harmonic LO leakage is shown in FIG. 7 as a plot 162. It can be seen that the second harmonic LO leakage level of the mixer using the diode ring array 106 is more than 15 dB lower when compared to the mixer having the single diode ring. The measured input 1 dB compression power is shown in FIG. 8 as a plot 172. The levels of linearity are similar between the mixer having the diode ring array 106 and the mixer having a single diode ring.

Therefore, it can be seen in FIGS. 7 and 8 that the sub-harmonic image rejection mixer having mixers with the diode ring array 106 has comparable linearity performance and lower second harmonic LO leakage levels than the sub-harmonic image rejection mixer having mixers with a single diode ring with larger diodes. Hence, by using the diode ring array in exemplary embodiments of the present invention, the leakage level can be reduced significantly without influencing other performance parameters of the mixer.

FIG. 9 is a block diagram of a transmitter 200 in another exemplary embodiment of the present invention. It can be seen that the sub-harmonic image rejection mixer is used as an up-converter to translate the spectrum of an input IF signal to an RF frequency signal centered around an RF frequency. The transmitter 200 includes IF processing circuitry 202 and a local oscillator 204, which provide an IF frequency signal and a LO frequency signal, respectively, to an MMIC 206. The MMIC 206 includes an LO amplifier 208 and a mixer 210. The output of the mixer 210 is provided to an antenna 216 via a filter 214. The main architectural difference between the transmitter 200 and the transmitter 100 of FIG. 3 is that the mixer 210 in the MMIC 206 includes two diode ring arrays 211 and 212, each having a plurality of (e.g., four) diode rings, to form a sub-harmonic image rejection mixer.

An IF hybrid 203 receives the IF signal having frequency ω₁, and generates two quadrature signals, IF₁ and IF₂, having the frequency ω₁ that are offset in phase by 90 degrees of each other. The IF₁ and IF₂ signals are provided to the diode ring arrays 211 and 212, respectively.

The LO frequency signal having the frequency ω₂/2 is amplified by the LO amplifier 208, and then divided by a power divider 209, which may include, for example, a Wilkinson power divider having a reduced size. In other embodiments, the LO amplifier may be implemented on a separate chip. In still other embodiments, the LO amplifier may be not used. The power divider 209 may also include any other suitable divider known to those skilled in the art. The divided signals having reduced power are provided to diode ring arrays 211 and 212, respectively. The outputs of the diode ring arrays 211 and 212 are combined, for example, by a 90° RF hybrid 213 in quadrature to generate an RF signal having frequency ω₁+ω₂. The 90° RF hybrid 213, for example, may include a Lange coupler or any suitable 90° RF hybrid known to those skilled in the art.

FIG. 10 is a block diagram of a parallel-connected diode ring array that represents each of the diode ring arrays 211 and 212. The diode ring array of FIG. 10 includes four diode rings 220, each of which has two anti-parallel diodes 222 and 224. At an input port 228 (i.e., IF and LO frequency signal input pad), the diode ring array is coupled to LO and IF frequency signals via a filter 229. Similarly, at the output port 226 (i.e., RF signal output pad), the diode ring array outputs the RF signal (i.e., transmission signal) through a filter 227. The filters 227 and 229, for example, may be implemented using a triplexer coupled to a connection point P between the diodes 220. The triplexer, for example, provides the high pass filter 227 for the RF frequency, and the low pass filter 229 for the LO and IF signals. The filters 227 and 229 have dual functions, besides filtering they provide impedance matching to the diodes and to LO+IF signals respectively.

The diode ring array 211 or 212 of FIG. 9 may also be used in the transmitter 100 of FIG. 3. Similarly, the diode ring array 112 of FIG. 4A or the diode ring array 130 of FIG. 4B may also be used in the transmitter 200 of FIG. 9.

In actual implementation, each of the four diode rings 220 in the diode ring arrays 211 and 212 is connected to a via hole for (e.g., optimum) RF, LO and IF return. On the other side the diode rings are connected to a single point, i.e., the connection point P. This arrangement allows equal sharing in magnitude and phase of applied voltage by each diode ring. In the individual ring, each diode has a gate width of 25 μm. Calculating the total effective size of the diodes, those four rings with two diodes each represent a diode ring with 200 μm gate width. During the implementation of the sub-harmonic image rejection mixer 210, spiral inductors and Metal-Insulator-Metal (MIM) capacitors may be used in the matching networks.

The LO amplifier 208, for example, may have two stages with device sizes, respectively, of 4×50 μm² and 6×50 μM², and may operate with a single supply voltage. To achieve the required bandwidth, distributed line elements in combination with MIM capacitors may be used. The inter-stage matching may conjugate match both stages for maximum gain. The output network may be optimized to deliver high output power. The selected load impedance can be extracted from load pull measurements of the transistor.

The local oscillator 204 and/or the LO amplifier 208 should present low second harmonic to minimize 2×LO feedthrough. In one specific implementation, the obtained level is close to −40 dBc compared to the fundamental power. This level may be further reduced by a tuned Wilkinson power combiner, and/or by the matching filter 229 described in reference to FIG. 10.

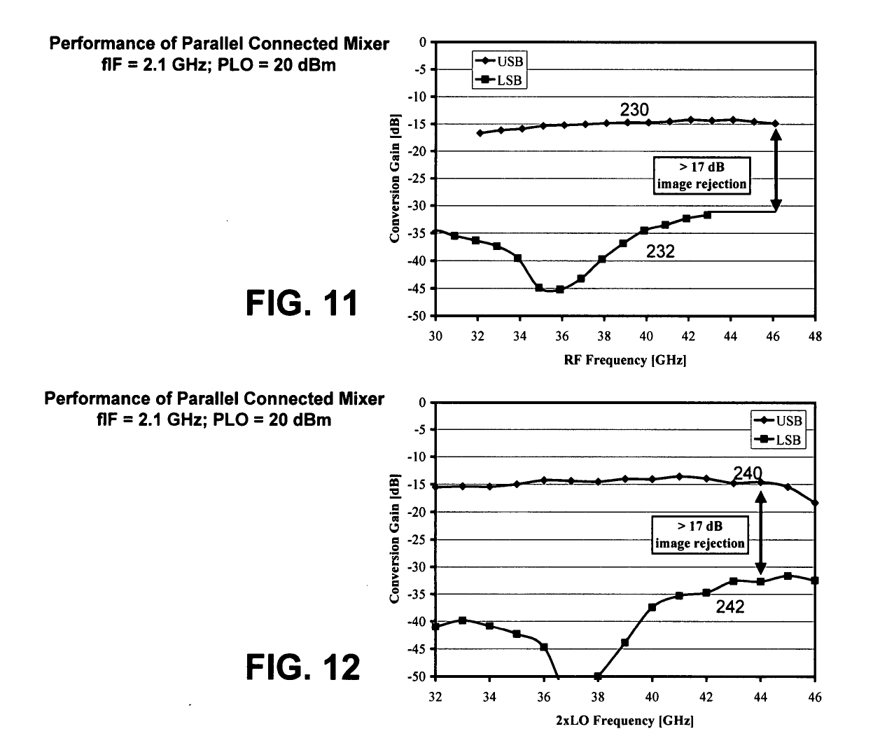

FIGS. 11 and 12 illustrate upper and lower side band gain plots taken while applying a single supply voltage of 5V to the LO amplifier 208. To compensate for temperature effects, the LO amplifier 208 is driven into deep compression. The applied input power level is 8 dBm. The MMIC is die attached to a metal carrier and wire bonded to the 90° IF hybrid 203, which is attached to a printed circuit board (PCB). The selected IF frequency is 2.1 GHz. The conversion loss of the sub-harmonic image rejection mixer 210, operating as a down-converter, is shown in FIG. 11. Within the frequency band from 36 to 44 GHz, the mixer 210 shows better than 15 dB conversion loss as seen in an upper side band (USB) conversion gain plot 230. At the same time, the image is rejected by more than 17 dB as can be seen by comparing the USB conversion gain plot 230 and a lower side band (LSB) conversion gain plot 232.

The measured up-converter results confirm the results obtained from down-converter operation. FIG. 12 shows the USB and LSB conversion gains 240 and 242, respectively, plotted versus 2×LO frequency. In the frequency band from 36 to 44 GHz, the conversion loss is between 14 and 15 dB. The image is suppressed by more than 17 dB over the band of operation.

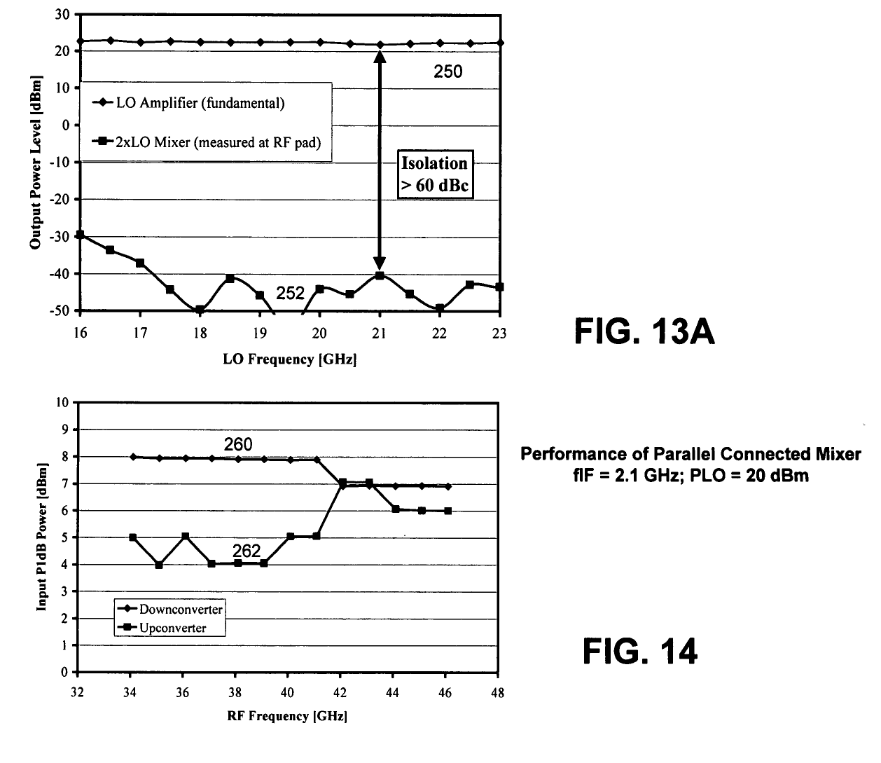

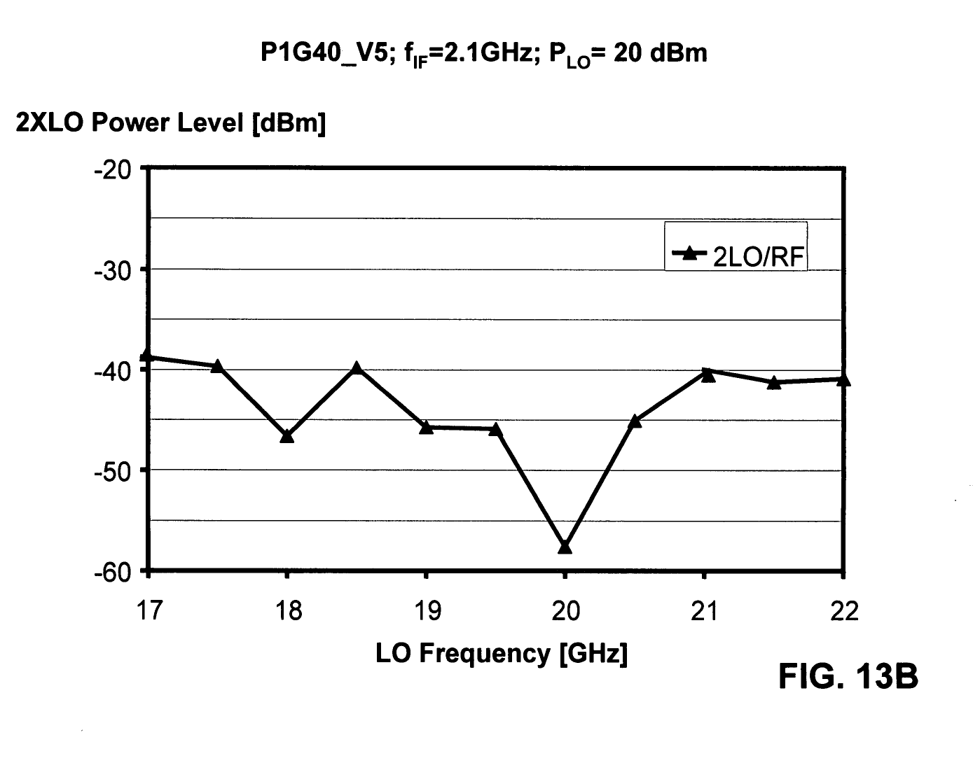

The LO generator operating from 18 to 22 GHz, which corresponds to a 2×LO frequency of 36 to 44 GHz, showed very low second harmonic at the output power level of +22 dBm. The 2×LO power level 252 measured at the RF bonding pad, i.e., at the mixer output, of the mixer with a parallel-connected diode ring array is depicted in FIG. 13A. In the frequency range from 18 to 22 GHz, the measured level is lower than −40 dBm. Thus the mixer provides a 2×LO to RF isolation of more than 60 dBc.

The result for the mixer with a series-connected diode ring array represented in FIG. 13B in a plot 324, as measured from the mixer output. The 2×LO power level is again lower than −40 dBm for the same applied LO power, providing more than 60 dBc of isolation.

The measured input 1 dB compression points for up- and down-converter operation is shown in FIG. 14. When used as a down-converter, the measured input P_{1dB} point is higher than 7 dBm as can be seen in an input P_{1dB} power plot 260. For up-converter operation, an input P_{1dB} point of more than 4 dBm is measured within the 36 to 44 GHz frequency band, as can be seen on an input P_{1dB} power plot 262.

FIG. 15 is a receiver 300 in an exemplary embodiment of the present invention. It should be noted that an LO amplifier 308 and a sub-harmonic image rejection mixer 310 implemented on a MMIC 306 has substantially the same structure as the LO amplifier 208 and the mixer 210, respectively, implemented on the MMIC 206 of FIG. 9. As such, the mixer 310 includes a power divider 309, diode ring arrays 311 and 312 and an a 90° RF hybrid 313 that have substantially the same structure and interconnection relationship as the power divider 209, the diode ring arrays 211 and 212, and the 90° RF hybrid 213, respectively, of FIG. 9. Therefore, the structure of the MMIC 306 will not be discussed in detail, and only the function of the receiver 300 will be described.

In the receiver 300, the mixer 310 is used for down-conversion of an RF signal to an IF signal. An antenna 316 receives the RF signal having the transmission frequency ω₁+ω₂, which is subsequently filtered by a filter 314. The filtered RF signal is provided to an RF hybrid 313, which generates quadrature signals, RF₁ and RF₂, that are at 90 degrees offset in phase of each other, and each having the frequency ω₁+ω₂. An LO 304 generates an LO frequency signal having the frequency ω₂/2. The LO frequency signal is amplified by an LO amplifier 308. The LO amplifier may be implemented on a separate chip or may be not used in other embodiments.

The power divider 309 divides the LO frequency signal and provides the divided LO frequency signals to the diode ring arrays 311 and 312, respectively. The diode ring arrays 311 and 312 also receive RF₁ and RF₂ signals, respectively. The image rejection mixer 310 generates IF1 and IF2 signals having frequency ω₁, and delivers them to an off-chip 90° IF hybrid 303 to generate an IF signal. The IF signal is then processed by the IF processing circuitry 316.

FIG. 16 is a graph illustrating the performance of a mixer built with the series-connected diode ring array of FIG. 4B. It can be seen in plots 320 and 322 that the power level difference between the LSB and USB are approximately 16 dB or more between 18 and 22 GHz. The plot 324 illustrates that the power level of 2×LO at RF is −40 dBm or more between 18 and 22 GHz.

It will be appreciated by those of ordinary skill in the art that the present invention can be embodied in other specific forms without departing from the spirit or essential character hereof. The present description is therefore considered in all respects to be illustrative and not restrictive. The scope of the present invention is indicated by the appended claims, and all changes that come within the meaning and range of equivalents thereof are intended to be embraced therein.

1. A sub-harmonic mixer comprising:
an input for receiving a first signal having a first frequency and a second signal having a second frequency;
an output for outputting a third signal having a third frequency; and
at least one diode ring array, each having a plurality of diode rings arranged in parallel,
wherein said at least one diode ring array receives the first signal and the second signal, generates a fourth signal having twice the second frequency, and multiplies the fourth signal to the first signal to generate the third signal.

2. The sub-harmonic mixer of claim 1, wherein said at least one diode ring array is coupled between at least one of the input and the output, and ground.

3. The sub-harmonic mixer of claim 1, wherein said at least one diode ring array is coupled between the input and the output.

4. The sub-harmonic mixer of claim 1, wherein said at least one diode ring array comprises two diode ring arrays that form an image rejection mixer.

5. The sub-harmonic mixer of claim 1, wherein the mixer performs up-conversion, wherein the third frequency is higher than the first frequency.

6. The sub-harmonic mixer of claim 5, wherein the first frequency is an IF frequency, the second frequency is an LO frequency, and the third frequency is an RF frequency.

7. The sub-harmonic mixer of claim 1, wherein the mixer performs down-conversion, wherein the first frequency is higher than the third frequency.

8. The sub-harmonic mixer of claim 7, wherein the first frequency is an RF frequency, the second frequency is an LO frequency, and the third frequency is an IF frequency.

9. A transmitter comprising:
a sub-harmonic mixer having at least one diode ring array, each having a plurality of diode rings arranged in parallel, the sub-harmonic mixer receiving an intermediate frequency (IF) signal and translating the IF signal to a transmission signal having a transmission frequency; and
an oscillator for generating a local oscillator (LO) frequency signal having an LO frequency,
wherein the sub-harmonic mixer receives the LO frequency signal, generates a signal having twice the LO frequency, and multiplies the signal having twice the LO frequency to the IF signal using said at least one diode ring array to generate the transmission signal.

10. The transmitter of claim 9, further comprising an LO amplifier for amplifying the LO frequency signal prior to multiplying the LO frequency signal to the IF signal.

11. The transmitter of claim 9, wherein each said diode ring array includes four diode rings.

12. The transmitter of claim 9, wherein the at least one diode ring array comprises two diode ring arrays.

13. The transmitter of claim 12, wherein the sub-harmonic mixer further comprises a power divider for dividing the LO frequency signal to generate two divided LO frequency signals, and providing the two divided LO frequency signals to the two diode ring arrays, respectively.

14. The transmitter of claim 12, further comprising a hybrid for receiving the IF signal and generating first and second quadrature IF signals that are provided to the two diode ring arrays, respectively.

15. The transmitter of claim 12, wherein the sub-harmonic mixer further comprises a hybrid for combining outputs of the two diode ring arrays to generate the transmission signal.

16. The transmitter of claim 9, further comprising a filter coupled to at least one of input and output ports of the sub-harmonic mixer.

17. The transmitter of claim 16, wherein the filter is implemented as a triplexer.

18. The transmitter of claim 9, wherein the sub-harmonic mixer is implemented on an MMIC chip.

19. The transmitter of claim 9, wherein the diode rings are coupled between a common connection point and ground.

20. The transmitter of claim 9, wherein the diode rings are coupled between input and output ports of the sub-harmonic mixer.

21. The transmitter of claim 9, wherein the transmission frequency includes at least one of a sum of said twice the LO frequency and the intermediate frequency, and a difference between said twice the LO frequency and the intermediate frequency.

22. A method of generating a transmission signal having a transmission frequency from an intermediate frequency (IF) signal, comprising:
generating a local oscillator (LO) frequency signal having an LO frequency;
generating a signal having twice the LO frequency using a sub-harmonic mixer including at least one diode ring array, each having a plurality of diode rings arranged in parallel; and
multiplying the signal having twice the LO frequency to the IF signal using the sub-harmonic mixer to generate the transmission signal.

23. The method of claim 22, wherein each said diode ring array includes four diode rings.

24. The method of claim 22, wherein the at least one diode ring array comprises two diode ring arrays.

25. The method of claim 24, further comprising dividing the LO frequency signal to generate two divided LO frequency signals, and providing the two divided LO frequency signals to the two diode ring arrays, respectively.

26. The method of claim 24, further comprising combining outputs of the two diode rings arrays to generate the transmission signal.

27. The method of claim 24, further comprising generating first and second quadrature IF signals using the IF signal, and providing the first and second quadrature IF signals to the two diode ring arrays, respectively.

28. The method of claim 22, further comprising filtering a signal on at least one of input and output ports of the sub-harmonic mixer.

29. A receiver comprising:
a sub-harmonic mixer having at least one diode ring array, each having a plurality of diode rings arranged in parallel, the sub-harmonic mixer receiving a transmission signal having a transmission frequency and translating the transmission signal to an intermediate frequency (IF) signal; and
an oscillator for generating a local oscillator (LO) frequency signal having an LO frequency,
wherein the sub-harmonic mixer receives the LO frequency signal, generates a signal having twice the LO frequency, and applies the signal having twice the LO frequency to the transmission signal using said at least one diode ring array to generate the IF signal.
